(19) United States
(12) Patent Application Publication
(10) Pub. No.: US 2019/0214950 A1
(43) Pub. Date: Jul. 11, 2019

(54) SWITCHED-MODE AUDIO AMPLIFIER EMPLOYING POWER-SUPPLY AUDIO-MODULATION

(71) Applicant: Avnera Corporation, Beaverton, OR (US)

(72) Inventor: Patrick Allen Quinn, Aloha, OR (US)

(21) Appl. No.: 16/294,652

(22) Filed: Mar. 6, 2019

Related U.S. Application Data
(63) Continuation of application No. 13/915,805, filed on Jun. 12, 2013, now abandoned.

(51) Int. Cl. H03F 3/185; H03F 3/217; H03F 1/02; H02M 3/158

(52) U.S. Cl. CPC H03F 3/185; H03F 3/2171; H03F 2200/03; H02M 3/158; H03F 1/0233

(57) ABSTRACT

A device and method are disclosed for modulating a power converter based on an audio signal to directly drive a speaker with a differential audio output signal. A first modulation signal and a second modulation signal are generated based on an input audio signal so that the first and second modulation signals are complementary signals to each other. In one embodiment, a feedback signal, such as an acoustic feedback signal from the speaker, is also used to generate the first and second modulation signals. A power supply voltage is modulated with the first modulation signal to generate a first voltage signal. The power supply voltage is also modulated with the second modulation signal to generate a second voltage signal. The first and second voltage signals form a differential audio signal that is used to drive the speaker. Alternatively, the power converter can drive a speaker with a single-ended output signal.

### CROSS-REFERENCE TO RELATED APPLICATIONS

This application is a continuation of co-pending U.S. patent application Ser. No. 13/915,805, filed Jun. 12, 2013, entitled “SWITCHED-MODE AUDIO AMPLIFIER EMPLOYING POWER-SUPPLY AUDIO-MODULATION,” the disclosure of which is incorporated herein by reference in its entirety.

### BACKGROUND

The subject matter disclosed herein relates to audio amplifier devices. More specifically, the subject matter disclosed herein relates to an audio amplifier that is configured as a power converter having a reference that is modulated based on an audio signal and that directly drives a speaker with a differential audio output signal.

### BRIEF DESCRIPTION OF THE DRAWINGS

The subject matter disclosed herein is illustrated by way of example and not by limitation in the accompanying figures in which like reference numerals indicate similar elements and in which:

FIG. 1 depicts a block diagram of an exemplary embodiment of a switched-mode audio amplifier that provides an audio output that is generated by directly modulating the input power supply according to the subject matter disclosed herein

FIG. 2 depicts a functional block diagram of one exemplary embodiment of a switched-mode audio amplifier that provides an audio output that is generated by directly modulating the input power supply according to the subject matter disclosed herein;

FIG. 3 depicts a more detailed functional block diagram of an exemplary embodiment of a switched-mode audio amplifier according to the subject matter disclosed herein;

FIG. 4 depicts an exemplary embodiment of a switched-mode audio amplifier in which the modulated regulators comprise modulated buck regulators according to the subject matter disclosed herein;

FIG. 5 depicts an exemplary embodiment of a switched-mode audio amplifier in which the modulated regulators comprise modulated SEPIC-type regulators according to the subject matter disclosed herein; and

FIG. 6 depicts a flow diagram for one exemplary process for generating a differential audio output by directly modulating a power converter by an audio signal according to the subject matter disclosed herein.

### DETAILED DESCRIPTION

As used herein, the word “exemplary” means “serving as an example, instance, or illustration.” Any embodiment described herein as “exemplary” is not to be construed as necessarily preferred or advantageous over other embodiments. Additionally, it will be appreciated that for simplicity and/or clarity of illustration, elements illustrated in the figures have not necessarily been drawn to scale. For example, the dimensions of some of the elements may be exaggerated relative to other elements for illustrative clarity. Further, in some figures only one or two of a plurality of similar elements indicated by reference characters for illustrative clarity of the figure, whereas all of the similar element may not be indicated by reference characters. Further still, it should be understood that although some portions of components and/or elements of the subject matter disclosed herein have been omitted from the figures for illustrative clarity, good engineering, construction and assembly practices are intended.

Embodiments of the subject matter disclosed herein relates to an audio amplifier configured as a power converter having a reference that is modulated by an incoming audio signal and to directly drive a speaker with a differential audio output signal. Much of the cost of an audio amplifier product is associated with generating the power supply voltages for the amplifier output and embodiments of the subject matter herein provide a lower cost approach for generating an audio signal that can drive a speaker. Embodiments of the subject matter disclosed herein convert input power, which can be either AC power or DC power, into an amplified-audio signal that is delivered to speakers. High fidelity is provided by utilizing negative feedback to compare the signals delivered to the speakers (or alternatively an acoustic feedback from those speakers) to an incoming audio source signal.

In one exemplary embodiment, the subject matter disclosed herein is configured as a DC/DC power converter having a reference that is modulated by an audio signal and to directly drive a speaker with a differential audio output signal. In an alternative exemplary embodiment, the subject matter disclosed herein is configured as an AC/DC converter having a reference that is modulated by an audio signal and to directly drive a speaker with a differential audio output signal. Accordingly, because the subject matter disclosed herein directly modulates a power converter with an audio signal, the costs associated with an audio amplifier comprising a separate power supply and a separate Class-D amplifier are reduced. As a benefit, the subject matter disclosed herein instantaneously generates only the supply voltage that is needed as the output audio signal. Thus, the subject matter disclosed wherein provides an audio amplifier in which a listener is more or less listening to the power supply of the audio amplifier. An additional benefit is that this architecture is considerably more efficient than a conventional Class-D amplifier because it avoids losses from both power-supply generation and the switching amplifier. In yet another exemplary embodiment, a Switched-Mode Power Supply (SMPS) converts input power, which can be either AC power or DC power, to an audio signal instead of a DC output voltage. An audio input signal, which modulates the SMPS to provide an amplified-audio signal for driving speakers, is used in place of a DC reference signal.

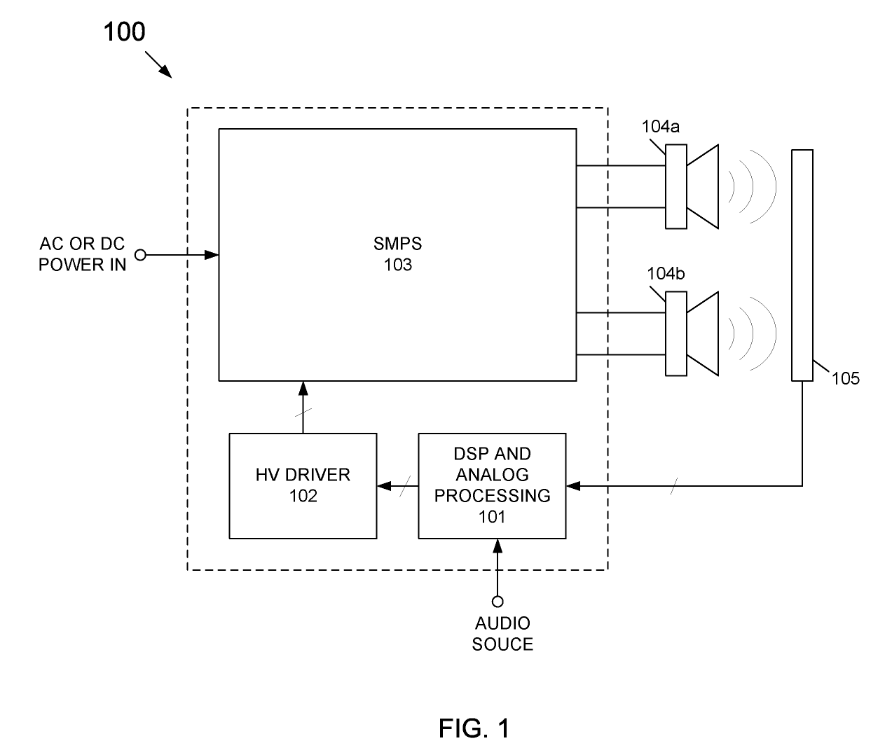

FIG. 1 depicts a block diagram of an exemplary embodiment of a switched-mode audio amplifier 100 that provides an audio output that is generated by directly modulating the input power supply according to the subject matter disclosed herein. A signal, which could be digital or analog, from an audio source that is to be amplified, is applied to a Digital Signal Processing (DSP) and Analog Processing 101. One or more outputs from DSP and Analog Processing 101 are output to a High Voltage (HV) Driver 102. One or more signals output from HV Driver 102 are input to a Switched-Mode Power Supply (SMPS) 103. SMPS 103 receives power from an AC or a DC input. If the input power is AC, the AC power could be any voltage and/or frequency, such as 110 or 220V, 60 or 50 Hz commercial power. In an alternative exemplary embodiment, DSP and Analog Processing 101 are configured to drive SMPS 103 directly. In one exemplary embodiment, SMPS 103 outputs differential amplified-audio signals to speakers 104a and 104b. In an alternative exemplary embodiment, SMPS 103 outputs single-ended audio signals to speakers 104a and 104b. An acoustic pickup 105 is used to provide one or more feedback signals to DSP and Analog Processing 101. Alternatively, one or more feedback signals could be generated directly from the amplified-audio signal driving speakers 104a and 104b. It should be understood that although two audio channels are shown, SMPS 103 could be configured to provide only a single differential amplified-audio signal.

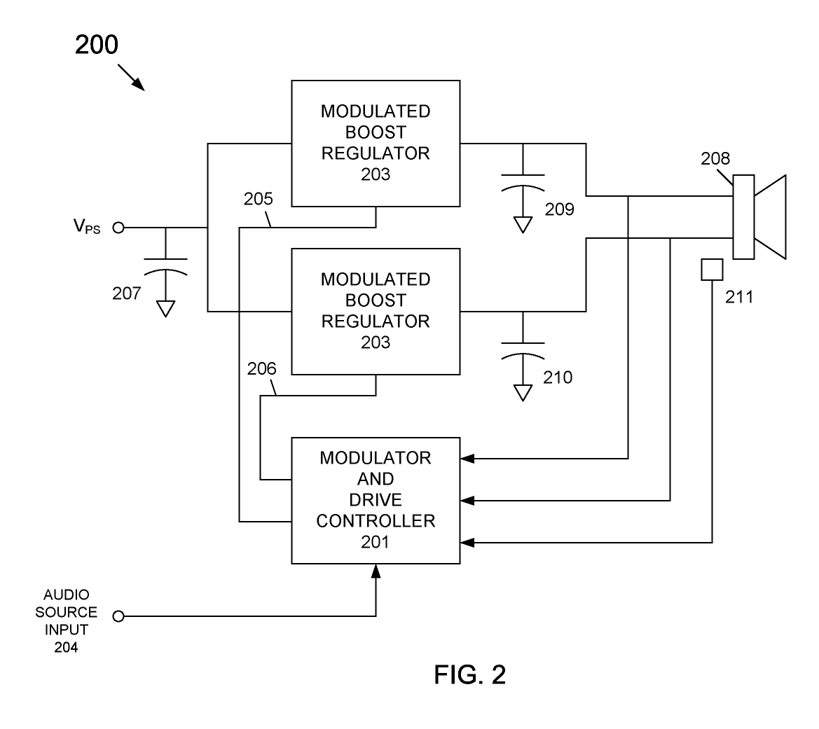

FIG. 2 depicts a functional block diagram of one exemplary embodiment of a switched-mode audio amplifier 200 that provides an audio output that is generated by directly modulating the input power supply according to the subject matter disclosed herein. Switched-mode audio amplifier 200 comprises a modulator and drive controller 201, a first modulated boost regulator 202 and a second modulated boost regulator 203. Modulator and drive controller 201 receives an audio source input 204, such as a pulse-width modulated (PWD) audio signal, and outputs complementary drive signals 205 and 206 to modulated boost regulators 202 and 203. Modulated boost regulators 202 and 203 are each coupled to a power supply voltage V_{PS}, which is filtered in a well-known manner by a capacitor 207. Because of the inherent differential nature of the design, variations that may occur in the value of V_{PS} are first-order rejected by virtue of the CMRR (Common-Mode Rejection Ratio) of the design. Modulated boost regulators 202 and 203 operate as single-ended DC/DC converters that are respectively directly modulated by complementary drive signals 205 and 206 to generate two Class-D outputs. There are other ways that are possible to produce the differential drive to a speaker 208 in addition to modulating each side single ended. For example, it would also be possible to generate the signal driving speaker 208 differentially at the output of a single modulator and control the common-mode aspect of those signals to ensure that each of the two speaker inputs (i.e., the modulator outputs) stays above some desired minimum operating voltage. For example, the minimum voltage might be 0V, or perhaps 2V. The Class-D output of modulated boost regulators 202 and 203 are respectively filtered in a well-known manner by capacitors 209 and 210 and differentially coupled to speaker 208. A microphone 211 located in proximity to speaker 208 provides an input for an acoustic feedback signal, which is coupled to modulator and drive controller 201 to close the feedback loop. In one exemplary embodiment, electrical feedback from the speaker inputs is used instead of acoustic feedback. An advantage of the acoustic feedback is that it would reduce the notoriously-poor linearity of speakers that can easily reach 2% non-linearity. Additional feedback signals can also be coupled from the differential outputs to modulator and drive controller 201. Moreover, it is possible to employ acoustic and electrical feedback in yet another exemplary embodiment of the subject matter disclosed herein.

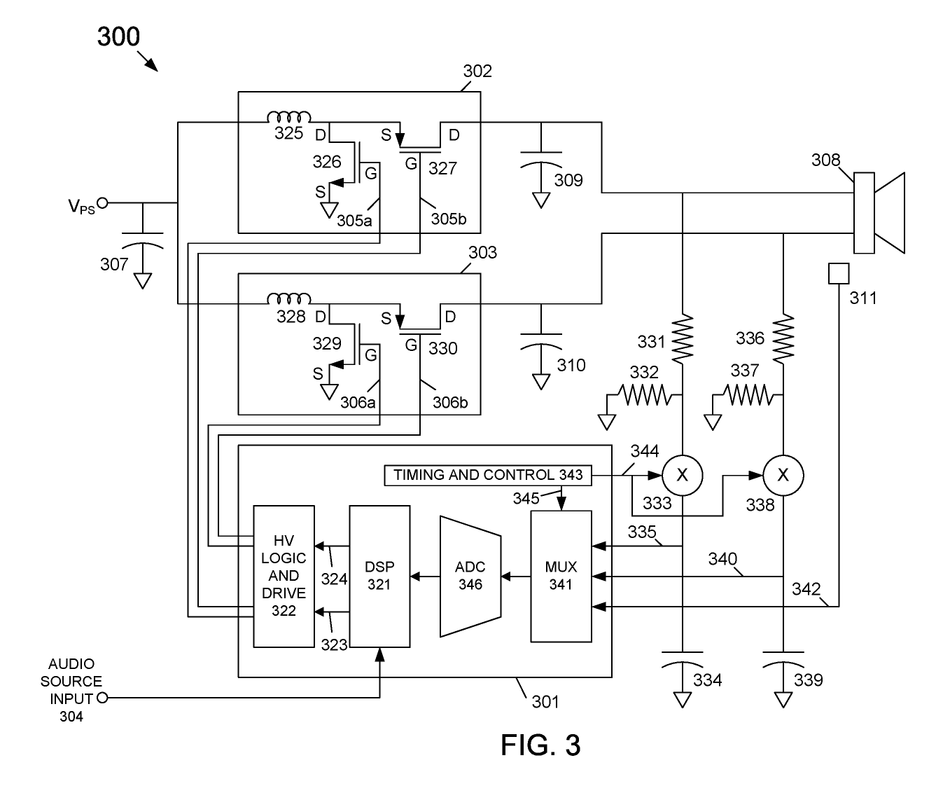

FIG. 3 depicts a more detailed functional block diagram of an exemplary embodiment of a switched-mode audio amplifier 300 according to the subject matter disclosed herein. Switched-mode audio amplifier 300 comprises a modulator and drive controller 301, a first modulated boost regulator 302 and a second modulated boost regulator 303.

Modulator and drive controller 301 comprises a digital signal processor (DSP) 321 that is coupled to a high-voltage (HV) logic and drive circuit 322. DSP 321 receives an audio source input 304, such as a pulse-width modulated (PWD) audio signal, and outputs drive signals 323 and 324 to HV logic and drive circuit 322. HV logic and drive circuit 322 conditions and converts signals 323 and 324 in a well-known manner from low-voltage signals to high-voltage signals 305 and 306 that are capable of driving modulated boost regulators 302 and 303. In some exemplary embodiments, the HV logic portion and the drive portion of HV logic and drive circuit 322 may comprise a separate functional blocks. Additionally, in one exemplary embodiment, DSP functional block 321 may comprise general-purpose microprocessor control functions. In some exemplary embodiments, the general control functions for DSP 321 may comprise in a separate functional block.

Modulated boost regulator 302 comprises inductor 325, a switching Field Effect Transistor (FET) 326 and an active pass device 327. Power supply V_{PS}, which is filtered in a well-known manner by capacitor 307, is coupled to one terminal of inductor 325. The other terminal of inductor 325 is coupled to the drain terminal of FET 326 and to the source terminal of active pass device 327. The gate terminal of FET 326 is coupled to HV drive signal 305a. The source terminal of FET 326 is coupled to system common or ground (i.e., a return path for the V_{PS} power supply). The gate of active pass device 327 is coupled to HV drive signal 305b, and the drain terminal of active pass device 327 is coupled to one terminal of filter capacitor 309.

In one exemplary embodiment, HV drive signal 305a comprises a PWM signal corresponding to audio source input 304 as processed by DSP 321. HV drive signal 305a has also been conditioned and scaled in voltage to be capable of driving FET 326 between on and off states. As FET 326 is driven between on and off states, inductor 325 generates a stepped-up voltage from input power supply V_{PS} to a desired output voltage level for driving speaker 308. Additionally, as FET 306 is driven between on and off states, FET 326 operates as a Class-D amplifier for audio input signal 304. Active pass device 327, which is configured to operate as a diode, in combination with capacitor 309 lowpass filters the output of ringing inductor 325 and FET 326. HV drive signal 305b controls the operation of active pass device 327. Signals 305a and 305b are essentially in phase electrically, except for the addition of non-overlapping timing to avoid both FET 326 and FET 327 being on at the same time.

Modulated boost regulator 303 is similar to modulated boost regulator 302 and comprises a ringing inductor 328, a switching FET 329 and an active pass device 330. Power supply V_{PS} is coupled to one terminal of inductor 328. The other terminal of inductor 328 is coupled to the drain terminal of FET 329 and to the source terminal of active pass device 330. The gate terminal of FET 329 is coupled to HV drive signal 306a. The source terminal of FET 329 is coupled to system common or ground (i.e., a return path for the V_{PS} power supply). The gate of active pass device 330 is coupled to HV drive signal 306b, and the drain terminal of active pass device 330 is coupled to one terminal of filter capacitor 310.

In one exemplary embodiment, HV drive signal 306a comprises a PWM signal corresponding to audio source input 304 as processed by DSP 321. HV drive signal 306a has also been scaled in voltage to be capable of driving FET 329 between on and off states. As FET 329 is driven between on and off states, inductor 328 generates a stepped-up voltage from input power supply V_{PS} to a desired output voltage level for driving speaker 308. Similar to FET 326, as FET 329 is driven between on and off states; FET 329 operates as a Class-D amplifier for audio input signal 304. Active pass device 330, which is configured to operate as a diode, in combination with capacitor 310 lowpass filters the output of ringing inductor 328 and FET 329. HV drive signal 306b controls the operation of active pass device 327.

HV drive signals 305 and 306 are modulated so that they are complements of each other and so that the signals appearing on capacitors 309 and 310 are compliments of each other. That is, drive signals 305 and 306 produce a differential output signal at the outputs of first and second modulated boost regulators 302 and 303 that is coupled to speaker 308. In one exemplary embodiment, HV drive signals are modulated using a pulse-width modulation (PWM) technique. In another exemplary embodiment, HV drive signals 305 and 306 are modulated using another modulation technique, such as, but not limited to, a pulse-density modulation (PDM) technique. In another exemplary embodiment, the HV signals 305 and 306 may be modulated using a hybrid technique, such as using PDM at low signal levels and PWM at higher signal levels. Generally, it is important to include a non-overlapping timing between signals 205a and 305b—and likewise between signals 306a and 306b to ensure that the two aspects of the boost regulator (charging up the input inductor) and outputting current into the output capacitor are not attempted at the same time.

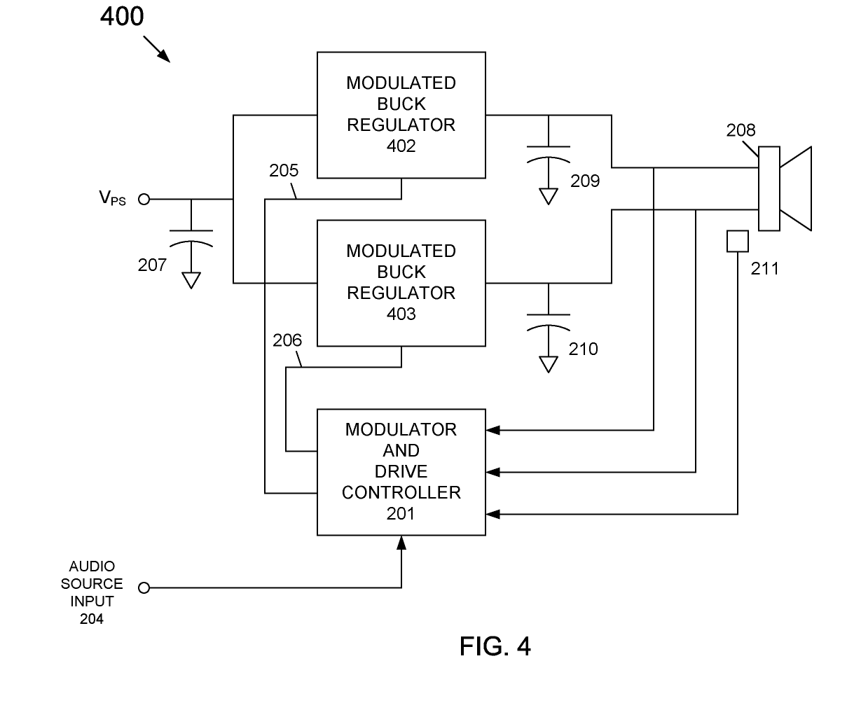

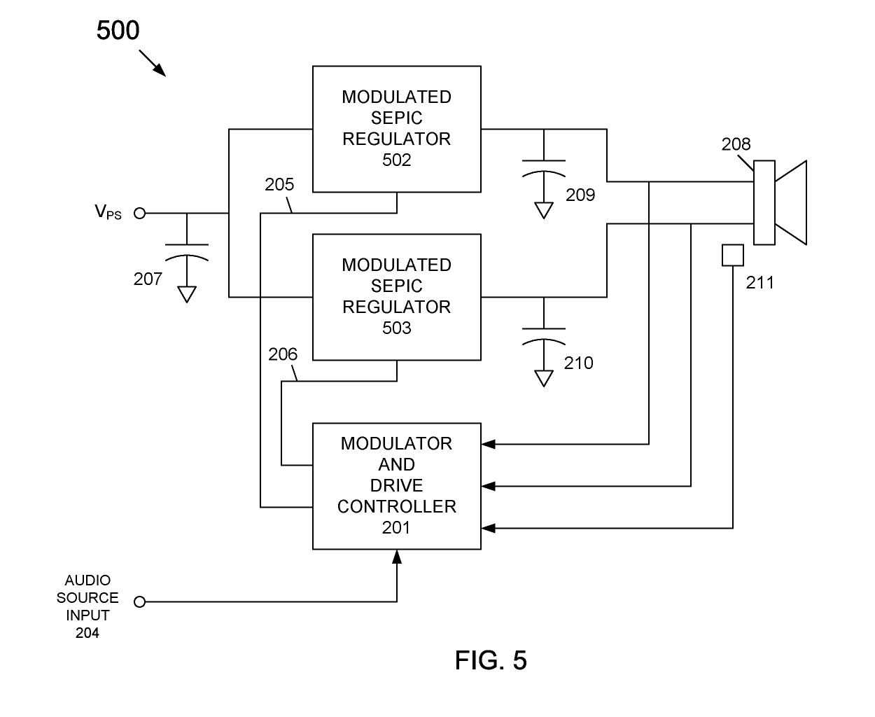

Modulated boost regulators 202 and 203 (302 and 303) are characterized as “boost” regulators because for the exemplary embodiments depicted in FIGS. 2 and 3, the output signal driving speaker 208 (308) is greater than the fixed input voltage V_{PS}. The subject matter disclosed herein is not so limited and the modulators may be of a different type. For example, in an embodiment in which the output signal driving speaker 208, 308 is less than the fixed input voltage V_{PS}, modulated regulators 202 and 203 (302 and 303) would be configured to be “buck” regulators. FIG. 4 depicts an exemplary embodiment of a switched-mode audio amplifier 400 in which modulated regulators 402 and 403 comprise modulated buck regulators. In an embodiment in which the output signal driving speaker 208, 308 can be greater than, equal to, and less than fixed input voltage V_{PS}, modulated regulators would be single-ended primary-inductor converter (SEPIC) type regulators. FIG. 5 depicts an exemplary embodiment of a switched-mode audio amplifier 500 in which modulated regulators 502 and 503 comprise modulated SEPIC-type regulators. Additionally, it should be understood that one exemplary embodiment of the subject matter disclosed herein comprises a single modulated regulator formed from any of the like-kind modulated regulators depicted in FIGS. 1-5 that outputs a differential output that drives speaker 208 (308). It should also be understood that the subject matter disclosed herein can alternatively be configured as an AC/DC converter having a reference that is modulated by an audio signal and to directly drive a speaker with a differential audio output signal.

Referring again to FIG. 3, in one exemplary embodiment, a first feedback network is coupled to the output of modulated boost regulator 302, and a second feedback network is coupled to the output of modulated boost regulator 303. The first feedback network comprises a resistor 331, a resistor 332, a switch 333, and a sampling capacitor 334. Resistors 331 and 332 form a resistor divider network that appropriately scale the first feedback signal for subsequent processing. Switch 333, under control from timing and control 342, passes the scaled feedback signal 335 to capacitor 334, which is input to a first input to a multiplexer (MUX) 341.

The second feedback network comprises a resistor 336, a resistor 337, a switch 338, and a sampling capacitor 339. Resistors 336 and 337 form a resistor divider network that appropriately scale the second feedback signal. Switch 338, under control from timing and control 343, passes the scaled feedback signal 340 to capacitor 339, which is input to a second input to MUX 341.

A microphone 311, which is placed in proximity to speaker 308, provides an acoustic feedback signal 342 by sampling the acoustic backwave of speaker 308. In an alternative exemplary embodiment, microphone 311 could be configured to sample the acoustic frontwave of speaker 308. Acoustic feedback signal 342 is input to a third input to MUX 341. In one exemplary embodiment, microphone 311 is placed in proximity to speaker 308, such as within the enclosure for speaker 308, to sense the actual speaker acoustic output. The acoustic feedback signal is then fed back through MUX 341 and DSP 321 to improve the sound quality of speaker 308. That is, DSP 321 applies corrections to drive signals 305 and 306 that account for the speaker enclosure cabinet impulse response, the impulse response of microphone 311, the spectral and dynamic speaker errors, or any desired spatialization or equalization, or a combination thereof. Acoustic feedback signal 342 can be calibrated to ensure that the signal is a faithful representation of the frontwave acoustic signal radiated from the front of speaker 308. In one exemplary embodiment, such calibration can comprise, but is not limited to, a characterization of the relationship between the frontwave and the backwave signals, a characterization of microphone 311, and a characterization of the frequency response of the backwave enclosure so that sources of error between the frontwave of speaker 308 and the signal picked up by microphone 321 are characterized and calibrated.

The specific feedback circuit details may vary depending on the specific system requirements for getting the signals at the drains of FET 327 and FET 330 fed back to the system DSP (or microprocessor). In some exemplary embodiments, the signals output from FETs 327 and 330 may need to be scaled (such as by, for example, resistors 331, 332, 336 and 337.) In some exemplary embodiments, MUX 341 may or may not be used. In some exemplary embodiments, a Nyquist analog-to-digital (ADC) may be used and samplers 333 and 338 may not be used. The important concept here is that the signals at the outputs of the modulated regulators can be fed back to the amplifier control and used as negative feedback.

Timing and control 343 outputs a sampling signal 344 and a MUX selection signal 345. Sampling signal 344 controls the timing of the sampling of feedback signals 335 and 340. MUX selection signal 345 controls which input to MUX 341 is passed through to Analog-to-Digital Converter (ADC) 346. ADC 346 generates a digital signal representation of the selected feedback signal in a well-known manner, which is input to DSP 321. DSP processes the various feedback signals in combination with audio source input 304 in a well-known manner to generate drive signals 323 and 324 to HV logic and drive circuit 322. In one exemplary embodiment, DSP 321 determines a difference signal between the incoming digital audio and the digitized feedback signal (or signals). The difference signal is then applied to a loop filter function that provides gain and noise shaping in a well-known manner. In one exemplary embodiment, the output of DSP 321 is a gained-up and filtered error signal that is converted in a well-known manner into a PWM or PDM signal. In another exemplary embodiment, DSP 321 provides auto-calibration functionality, such as, but not limited to, Common Mode Rejection Ratio (CMRR) calibration.

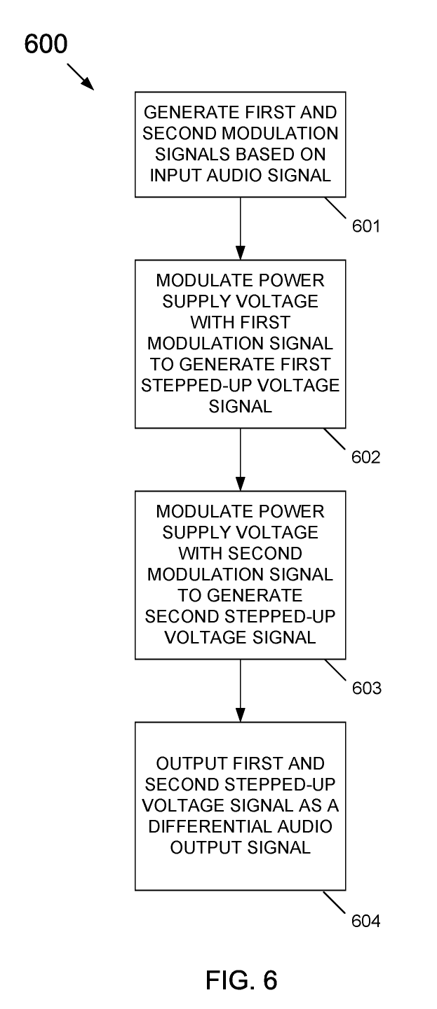

FIG. 6 depicts a flow diagram for one exemplary process 600 for generating a differential audio output by directly modulating a power converter by an audio signal according to the subject matter disclosed herein. At 601, a first modulation signal and a second modulation signal are generated based on an input audio signal. According to the subject matter disclosed herein, the first and second modulation signals are complementary to each other in order to produce a differential audio output signal. In one exemplary embodiment, the first and second modulation signals are generated based on the input audio signal and at least one feedback signal. In one exemplary embodiment, the at least one feedback signal comprises an acoustic feedback signal of a speaker coupled to the differential audio signal. In another exemplary embodiment, the at least one feedback signal includes a first feedback signal corresponding to the first stepped-up voltage signal and a second feedback signal corresponding to the second stepped-up voltage signal. In yet another exemplary embodiment, the first and second modulation signals comprise pulse-width modulated (PWM) signals or pulse-density modulated (PDM) signals, or a combination thereof. At 602, a power supply voltage is modulated with the first modulation signal to generate a first stepped-up voltage signal. At the same time at 603, the power supply voltage is modulated with the second modulation signal to generate a second stepped-up voltage signal. At 604, the first and second stepped-up output signals are output as a differential audio output signal based on the complementary first and second modulation signals. Although the process disclosed in FIG. 6 relates to a stepped-up power converter, the subject matter disclosed herein is not so limited and can relate alternatively to a step-down power converter or a SEPIC power converter.

Although the foregoing disclosed subject matter has been described in some detail for purposes of clarity of understanding, it will be apparent that certain changes and modifications may be practiced that are within the scope of the appended claims. Accordingly, the present embodiments are to be considered as illustrative and not restrictive, and the subject matter disclosed herein is not to be limited to the details given herein, but may be modified within the scope and equivalents of the appended claims.

What is claimed is:

1. A switched-mode audio amplifier, comprising:
a modulator configured to receive an audio input signal and to output a first modulation signal and a second modulation signal based on the audio input signal;
a first regulator configured to generate a first voltage signal to drive a speaker by modulating a power supply voltage based on the first modulation signal, the first voltage signal corresponding to the audio input signal; and
a second regulator configured to generate a second voltage signal to drive the speaker by modulating the power supply voltage based on the first modulation signal, the first voltage signal corresponding to the audio input signal.

2. The switched-mode audio amplifier of claim 1 wherein the first modulation signal and the second modulation signal are complementary of each other.

3. The switched-mode audio amplifier of claim 1 wherein the modulator is further configured to receive the first voltage signal and the second voltage signal and output the first modulation signal and second modulation signal based on the first voltage signal and the second voltage signal.

4. The switched-mode audio amplifier of claim 1 wherein at least one of the first modulation signal and the second modulation signal comprises a pulse-width modulated signal or a pulse-density modulated signal.

5. The switched-mode audio amplifier of claim 1 wherein at least one of the first regulator and the second regulator comprises a boost regulator, a buck regulator, or a single-ended primary-inductor converter regulator.

6. The switched-mode audio amplifier of claim 1 further comprising a sensor configured to generate a feedback signal based on an output from the speaker.

7. The switched-mode audio amplifier of claim 6 wherein the feedback signal is an acoustic signal or an electric signal.

8. The switched-mode audio amplifier of claim 1 wherein the modulator is configured to output at least one of the first modulation signal and the second modulation signal based on the feedback signal.

9. A method for converting an input power supply voltage to an amplified-audio signal, comprising:
receiving an audio input signal;
receiving the input power supply voltage;
generating a first modulation signal based on the audio input signal;
generating a second modulation signal based on the audio input signal;
modulating the input power supply voltage to generate a first voltage signal to drive a speaker based on the first modulation signal; and
modulating the input power supply voltage to generate a second voltage signal to drive the speaker based on the second modulation signal.

10. The method of claim 9 wherein the first modulation signal and the second modulation signal are complementary of each other.

11. The method of claim 10 wherein the first voltage signal and the second voltage signal form a differential audio signal to drive the speaker

12. The method of claim 9 wherein generating the first modulation signal is based on the first voltage signal and generating the second modulation signal is based on the second voltage signal.

13. The method of claim 9 wherein at least one of the first modulation signal and the second modulation signal comprises a pulse-width modulated signal or a pulse-density modulated signal.

14. The method of claim 9 further comprising generating a feedback signal based on an output from the speaker.

15. The method of claim 14 wherein the feedback signal comprises an acoustic signal or an electric signal.

16. The method of claim 14 wherein generating the first modulation signal and generating the second modulation signal includes generating the first modulation signal and generating the second modulation signal based on the feedback signal.

17. The method of claim 16 wherein generating the first modulation signal further includes generating the first modulation signal and generating the second modulation signal based on at least one of the first voltage signal or the second voltage signal.

18. An audio device, comprising:
an input to receive an audio input signal;
a switched-mode audio amplifier, including:
a modulator configured to receive the audio input signal and to output a first modulation signal and a second modulation signal based on the audio input signal,
a first regulator configured to generate a first voltage signal to drive a speaker by modulating a power supply voltage based on the first modulation signal, the first voltage signal corresponding to the audio input signal, and
a second regulator configured to generate a second voltage signal to drive the speaker by modulating the power supply voltage based on the first modulation signal, the first voltage signal corresponding to the audio input signal; and
an output coupled to the speaker, the output configured to transmit the first voltage signal and the second voltage signal to the speaker.

19. The audio device of claim 18 further comprising a sensor configured to generate a feedback signal based on an output from the speaker.

20. The switched-mode audio amplifier of claim 19 wherein the feedback signal is an acoustic signal or an electric signal.
